(19) United States
(12) Patent Application Publication
(10) Pub. No.: US 2008/0297170 A1
(43) Pub. Date: Dec. 4, 2008

(54) DYNAMIC INDUCTANCE MEASUREMENT OF ELECTRIC MOTOR

(75) Inventors: Krishna N. H. Sri, Bangalore (IN); Mukesh Soni, Bangalore (IN); Narasimha Murthy K., Bangalore (IN)

Correspondence Address: THOMAS F. LENIHAN;TEKTRONIX, INC., 14150 S. W. KARL BRAUN DRIVE, P.O. BOX 500 (50-LAW), BEAVERTON, OR, 97077-0001, US

(73) Assignee: TEKTRONIX, INC., Beaverton, OR (US)

(21) Appl. No.: 12/124,481

(22) Filed: May 21, 2008

(30) Foreign Application Priority Data
May 28, 2007 (IN) 990/MUM/2007

(51) Int. Cl. G01R 27/02

(52) U.S. Cl. 324/603; 324/654

(57) ABSTRACT

A system, apparatus, and method for dynamic measurement of inductance trend of a motor are disclosed. In one of the embodiment herein the system is configured to acquire inputs from the DUT using a Trigger system, a horizontal subsystem and the programming unit. The system is also configured to process such information for dynamic analysis and representation on an interface provided in the system based on different step sizes.

### CLAIM FOR PRIORITY

The subject application claims priority under 35 U.S.C. 119 from Indian Provisional Patent Application No. 990/MUM/2007, entitled, DYNAMIC INDUCTANCE MEASUREMENT OF ELECTRIC MOTOR (Sri Krishna N. H., et al.), filed 28 May 2007, and from Indian Regular Patent Application No. 990/MUM/2007, entitled, DYNAMIC INDUCTANCE MEASUREMENT OF ELECTRIC MOTOR (Sri Krishna N. H., et al.), filed 14 May 2008.

### FIELD OF THE INVENTION

The present invention relates generally to instrumentation and more particularly to inductance measurement in real time.

### BACKGROUND OF THE INVENTION

Electric motors have wide industrial applications. An electric motor is a device for transforming electrical energy into mechanical energy; an electric generator does the reverse, using mechanical energy to generate electricity. At the heart of both motors and generators is a wire coil in a magnetic field. In fact, the same device can be used as a motor or a generator. In a motor, the rotor coil revolves on its axis dues to the rotating magnetic flux in the region between the stator and rotor coils.

A three-phase AC induction motor is a rotating electric machine designed to operate from a three-phase source of alternating voltage. A three phase AC induction motor typically includes three symmetrically-placed windings surrounding a rotor. The rotor is separated from the windings by an air gap. The three phase AC voltages may be thought of as being three independent AC power sources, all of which have the same amplitude and frequency, but exhibiting respective phases that are 2π radians/3 apart (i.e., displaced by 120° from one another). When the three AC voltages are applied to the windings, three currents flow through the (three) symmetrically placed windings, the sinusoidal distributed air gap flux is produced which generates current in the rotor. The currents, too, are sinusoidal functions of time, all at the same frequency but having different phases.

The principle of rotating magnetic fields is fundamental to the operation of most AC motors. Both synchronous and induction types of motors depend on the generated rotating magnetic fields in their stators (stationary windings) to cause their rotors to turn. When a startup winding is connected to the power source, the motor begins to turn. The rotating magnetic field is a magnetic field which periodically changes direction. The current flowing in an inductor depends upon the voltage applied to that inductor, the duration of the applied voltage, the inductance of the inductor, and the resistance of the inductor. The inductance of an inductor depends upon the change in magnetic flux which couples the windings as a function of the change in current flowing through the windings. When the permeability of a core of an inductor changes as a result of saturation, the inductance of the inductor itself changes. Specifically, the inductance decreases, and the current flowing in the windings increases thereby decreasing efficiency. That is, efficiency decreases because a substantial increase in winding current flow causes an increase of heating of the windings.

A designer of a motor may therefore need to measure such variations of inductances. One method for measuring inductance in real time scenario is provided in U.S. Pat. No. 6,876,936, MEASUREMENT OF INDUCTANCE USING A DIGITAL STORAGE OSCILLOSCOPE UNDER REAL-TIME OPERATING ENVIRONMENTS (P. E. Ramesh, et al), issued 5 Apr. 2005 (hereinafter Ramesh '936), and assigned to the same assignee as the subject application. Ramesh '936 discloses a method and apparatus for measuring inductance, which include processing current and voltage waveform data associated with an inductive device to determine edge and slope parameters for each of a plurality of current waveform data cycles. Furthermore, proportional magnetic flux and proportional magnetic current is determined from the acquired current waveform data and the voltage waveform data proximate determined edge regions of the waveform data. An inductance value of the inductive device may then be calculated from the proportional magnetic flux and proportional magnetic current.

However for measuring the changes in inductance with respect to rotor angle as in case of motor may not be possible using the teachings of Ramesh '936.

There is therefore a need of system to measure such variations in inductances to enable the designers of such systems manufacture better systems.

### SUMMARY OF THE INVENTION

A system, apparatus and a method for dynamic measurement of inductance trend of a motor are described. In one of the embodiment herein the system is configured to acquire inputs from the DUT using a Trigger system, a horizontal subsystem and the programming unit. The system is also configured to process such information for dynamic analysis and representation on an interface provided in the system based on different step sizes.

The apparatus may comprise of an input means for acquiring inputs signals from a motor. For example the input means may be the input probes. The apparatus also comprises a trigger system for defining acquisition cycle in accordance with the instructions from a programming unit.

A deflection subsystem for dynamic representation based on step size in accordance with the instruction from programming unit is also available in the apparatus. The trigger system and deflection subsystems may be configured to perform the operations as instructed by a programming unit of the apparatus. The programming unit configured to control the said trigger system and deflection subsystem and calculate induction with respect to rotor angle by repeated dynamic analysis of inputs signals from the motor for a chosen step size.

In one embodiment the method for dynamic measurement of inductance trend of a motor comprises of steps of acquiring input signal from a motor; receiving a step size for analysis from a user; calculating the inductance by dynamic analysis of the input signal for a chosen step size. In one embodiment the method used for calculating one instance of inductance is B-H method.

The method allows a user to dynamically test the variation of inductances of motors such as AC motors. The change of inductances with different angular positioning of the rotor is made available enabling them to design better motors.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. 1 shows according to an embodiment herein an apparatus for dynamic measurement of inductance trend of a motor.

FIG. 2a is a graph of a DUT voltage waveform acquired in accordance with one embodiment of the present invention.

FIG. 2b is a graph of a DUT current waveform acquired in accordance with one embodiment of the present invention.

FIG. 3 shows an integrated voltage waveform obtained using one embodiment of the present invention.

FIG. 4 shows windowed integral voltage and windowed current waveforms using one embodiment of the present invention.

FIG. 5 shows the BH-curve for scan window size=360° in accordance with one embodiment of the present invention.

FIG. 6 shows a method for dynamic measurement of inductance trend of a motor in accordance with one embodiment of the present invention.

FIG. 7 is a screenshot of the apparatus interface in accordance with one embodiment of the present invention.

FIG. 8 shows variation in inductance (L) with a scan window set to 360° as per an exemplary embodiment herein.

FIG. 9 shows variation in L with a scan window set to 90° as per an exemplary embodiment herein.

FIG. 10 show variation in L with a scan window set to 2.8° as per an exemplary embodiment herein.

FIG. 11 shows percentage variations of L versus varying scan window size as per an exemplary embodiment herein.

### DETAILED DESCRIPTION OF THE EMBODIMENTS

A system, apparatus and a method for dynamic measurement of inductance trend of a motor are described. In one of the embodiment herein the system is configured to acquire inputs from the DUT using a Trigger system, a horizontal subsystem and the programming unit. The system is also configured to process such information for dynamic analysis and representation on an interface provided in the system based on different step sizes. The DUT is generally the motor being tested in such scenario. The various types of motors may be used such as AC motors, DC motors etc.

In one embodiment, the said system may be provided in an apparatus such as a digital oscilloscope. In another embodiment the said features may be made available as a standalone application, which may be run on a computing device. The said standalone application may be a software code configured to perform steps in accordance with the method of the present invention.

The embodiments herein also provide a computer program and a computer program product for carrying out any of the methods described herein and/or embodying any of system features described herein, and a computer readable medium having stored thereon a program for carrying out any of the methods described herein.

In the following description, for purpose of explanation, specific details are set forth in order to provide an understanding of the invention. It will be apparent, however, to one skilled in the art that the invention may be practiced without these details. One skilled in the art will recognize that embodiments of the present invention, some of which are described below, may be incorporated into a number of different measurement systems. The embodiments of the present invention may be present in hardware, software or firmware. The best mode of the invention described in the specification illustrates the exemplary embodiment of the invention. It is understood that one skilled in art may modify or change the data used in the best mode of invention.

Reference in the specification to “one embodiment” or “an embodiment” means that a particular feature, characteristic, or function described in connection with the embodiment is included in at least one embodiment of the invention. The appearances of the phrase “in one embodiment” in various places in the specification are not necessarily all referring to the same embodiment.

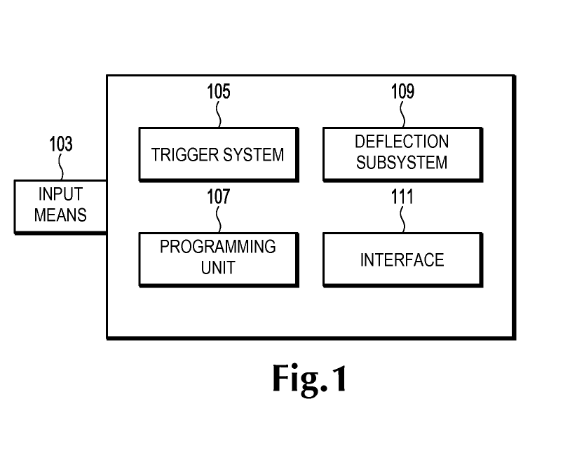

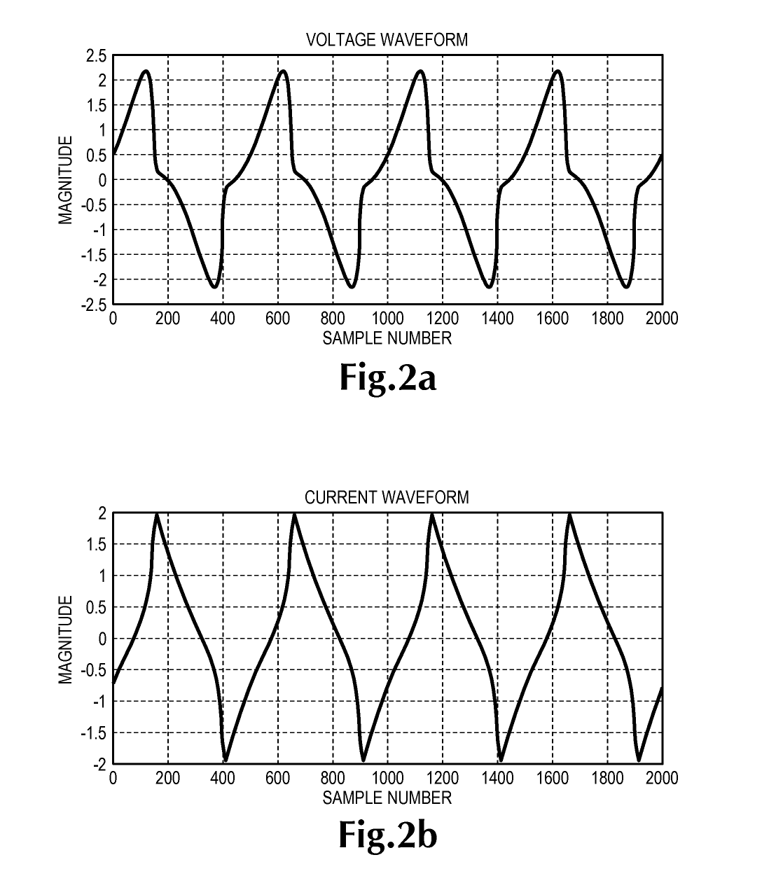

FIG. 1 shows, according to an embodiment herein, an apparatus for dynamic measurement of inductance trend of a motor. The apparatus comprises of an input means 103 for receiving information in form of signals from a device under test (DUT). FIG. 2a shows the voltage waveform acquired in accordance with one embodiment of the present invention. FIG. 2b shows the current waveform acquired in accordance with an embodiment of the present invention. A trigger system 105 is configured to define acquisition cycle in accordance with the instructions from a programming unit 107. Further, a deflection subsystem for dynamic representation based on step size in accordance with the instruction from programming unit is provided.

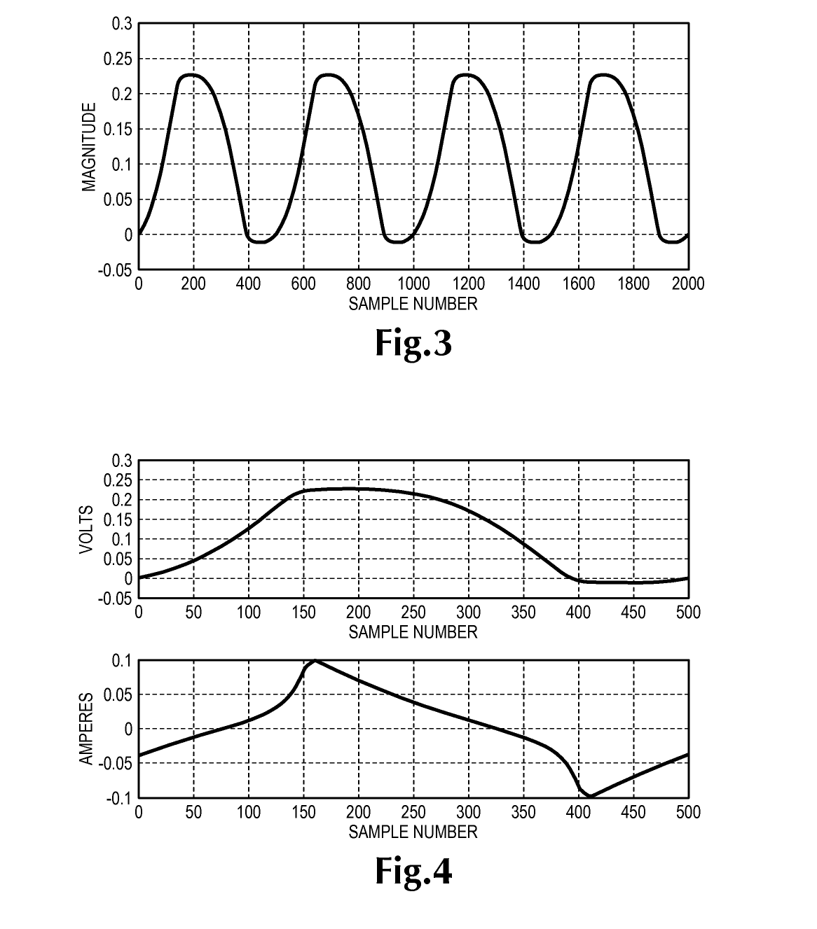

The programming unit is also configured to calculate the varying inductance by integrating each cycle of the voltage and current waveforms obtained during acquisition of input signals. FIG. 3 shows an integrated voltage waveform obtained using one embodiment of the present invention. In one embodiment the integration may be done using the trapezoidal method configured in the apparatus as explained below.

### Trapezoidal Rule:

First, the area under curve is divided into n strips, each equal to h=(b−a)/n where, b and a are the lower and upper limits of integration. The area of each strip is approximated to be that of trapezium the sum of these trapezoids areas gives an approximation for the definite integral. The shape of each strip is approximated to be like that of a trapezium. Hence, area of the first strip is approximately

h/2(f(a)+f(a+h)) Eq. (1)

Similarly, area of the ith strip can be approximated to be

$$\frac{h}{2} ( f ( a + ( i - 1 ) h ) + f ( a + i h ) ) \qquad Eq . ( 2 )$$

Adding up these areas gives an approximate value of definite integral:

$${\int }_{a}^{b} f ( x ) d x \approx {\sum }_{i = 1}^{n} \frac{h}{2} ( f ( a + ( i - 1 ) h ) + f ( a + ( i + 1 ) h ) ) \qquad Eq . ( 3 )$$

The apparatus is configured such that the user may choose the step size for his analysis of varying inductances with rotor angle. For example a step size of 360° would represent acquisitions of input signals from DUT, which are 360° apart. In this scenario the rotor would be at same position when each acquisition takes place. The programming unit is configured to control the trigger system for defining such acquisitions. FIG. 4 shows windowed integral voltage and windowed current waveforms using one embodiment of the present invention. The windowed integral voltage and windowed current waveforms are based on the step size chosen.

The programming unit is configured to further process the integral voltage and current waveforms to obtain inductance value. In one embodiment the inductance may be calculated using the B-H curve method.

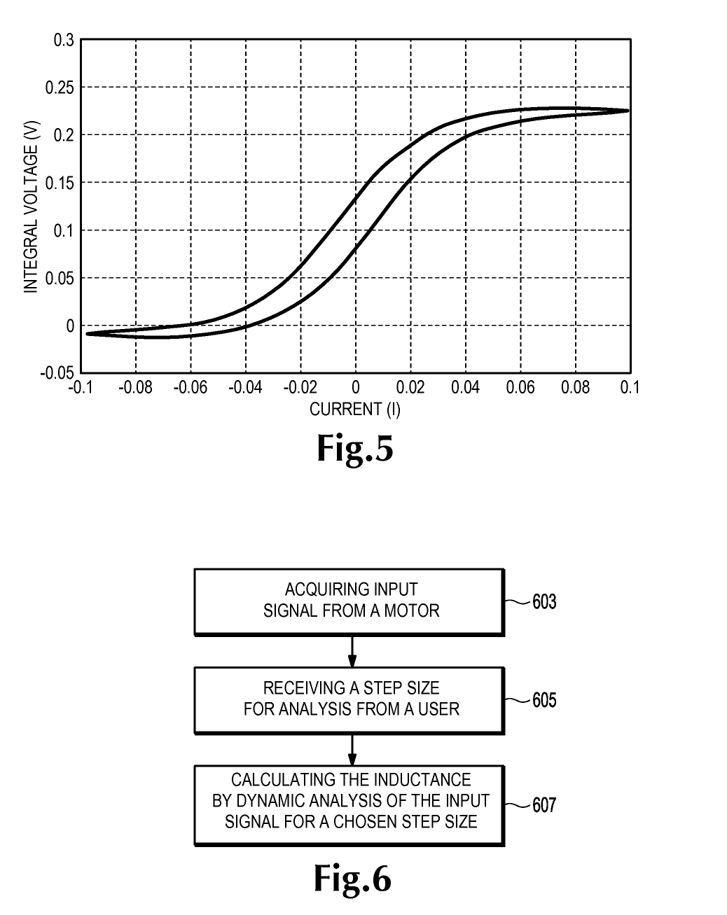

FIG. 5 shows the BH-curve for scan window size=360°. Below are the expressions used in the configuring the programming unit:

$$\begin{matrix}E = - L ( \frac{d i}{d t} ) & Eq . ( 4 ) \\ Integrating \int E d t = - L \int \frac{d i}{d t} d t & Eq . ( 5 )\end{matrix}$$

Rearranging terms and neglecting negative sign, we get:

$$L = ( \frac{\int E d t}{I} ) \qquad Eq . ( 6 )$$

The programming unit is also configured to obtain integral of the voltage waveform using trapezoidal method. This value is then divided by current waveform to obtain the value of L in programming unit. As the integrated voltage waveform and current waveforms are sampled, linear regression equation is used to calculate the value of L.

X=ΣXᵢ/N Eq. (7)

Y=ΣYᵢ/N Eq. (8)

|X|ᵢ=Xᵢ−X,i=1 . . . N Eq. (9)

|Y|ᵢ=Yᵢ−Y,i=1 . . . N Eq. (10)

Thus using the above expressions the inductance is calculated as shown in equation 9.

$$Thus Inductance L = \sum \frac{{\vert X \vert}_{i} {\vert Y \vert}_{i}}{{\vert X \vert}_{i}^{2}} \qquad Eq . ( 11 )$$

Where, X represents Current waveform and Y represents integral of Voltage waveform. The inductance is thus calculated and plotted for different rotor angles, for a specified step size.

According to an embodiment of the present invention a method for dynamic measurement of inductance trend of a motor is shown in FIG. 6. The motor forms the device under test (DUT) in this scenario. The method comprises the steps of acquiring 603 input signal from a motor. The input signals may comprise of current and voltage signals, which may be plotted to obtain current waveform and voltage waveform respectively. The voltage waveform and current waveform are integrated over an entire cycle.

Further the method involves receiving 605 step size from a user. For example the step size may be 360°. Further calculating 607 the inductance by dynamic analysis of the input signal for a chosen step size using following expressions occurs:

$$\begin{matrix}E = - L ( \frac{d i}{d t} ) & Eq . ( 21 ) \\ Integrating \int E d t = - L \int \frac{d i}{d t} d t & Eq . ( 22 )\end{matrix}$$

Rearranging terms and neglecting negative sign, we get:

$$L = ( \frac{\int E d t}{I} ) \qquad Eq . ( 23 )$$

The method involves integrating the voltage waveform using trapezoidal method. This value is then divided by current waveform to obtain the value of L. As the integrated voltage waveform and current waveforms are sampled, linear regression equation is used to calculate the value of L.

X=ΣXᵢ/N Eq. (24)

Y=ΣYᵢ/N Eq. (25)

|X|ᵢ=Xᵢ−X,i=1 . . . N Eq. (26)

|Y|ᵢ=Yᵢ−Y,i=1 . . . N Eq. (27)

Thus using the above expressions the inductance is calculated as shown in equation 28.

$$Thus Inductance L = \sum \frac{{\vert X \vert}_{i} {\vert Y \vert}_{i}}{{\vert X \vert}_{i}^{2}} \qquad Eq . ( 28 )$$

Where, X represents Current waveform and Y represents integral of Voltage waveform.

The above procedure of calculating the inductance is repeated to plot the value of inductance obtained with respect to angle of rotor based on the step size chosen. The inductance is thus calculated and plotted for different rotor angles, for a specified step size.

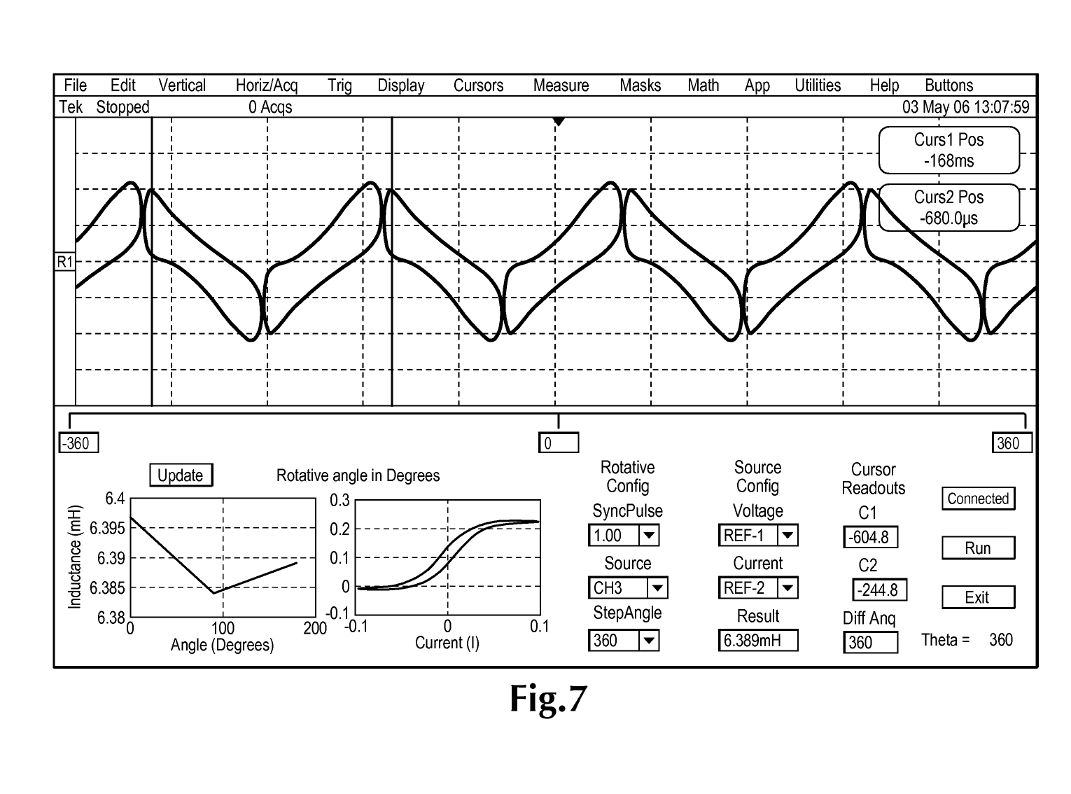

FIG. 7 is a screenshot of a system configured according to the method of the present invention.

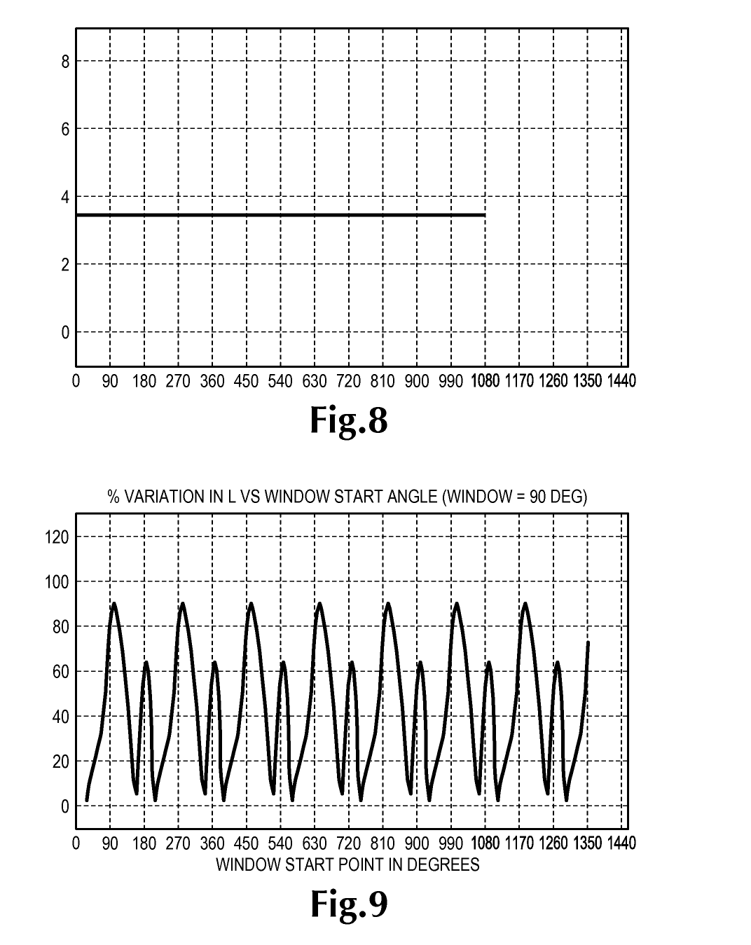

FIG. 8 shows a plot of variation of L versus window start point. Referring to FIG. 8, a scan step size is set to be equal to 360°, and then the window is swept over the record length. The results displayed in FIG. 8, shows no variation in the value of L.

FIG. 9 shows a plot of variation of L versus window start point. With step size reduced to 90°, the scan window is once again swept over the record length. The results show variation of up to 80% in value of L.

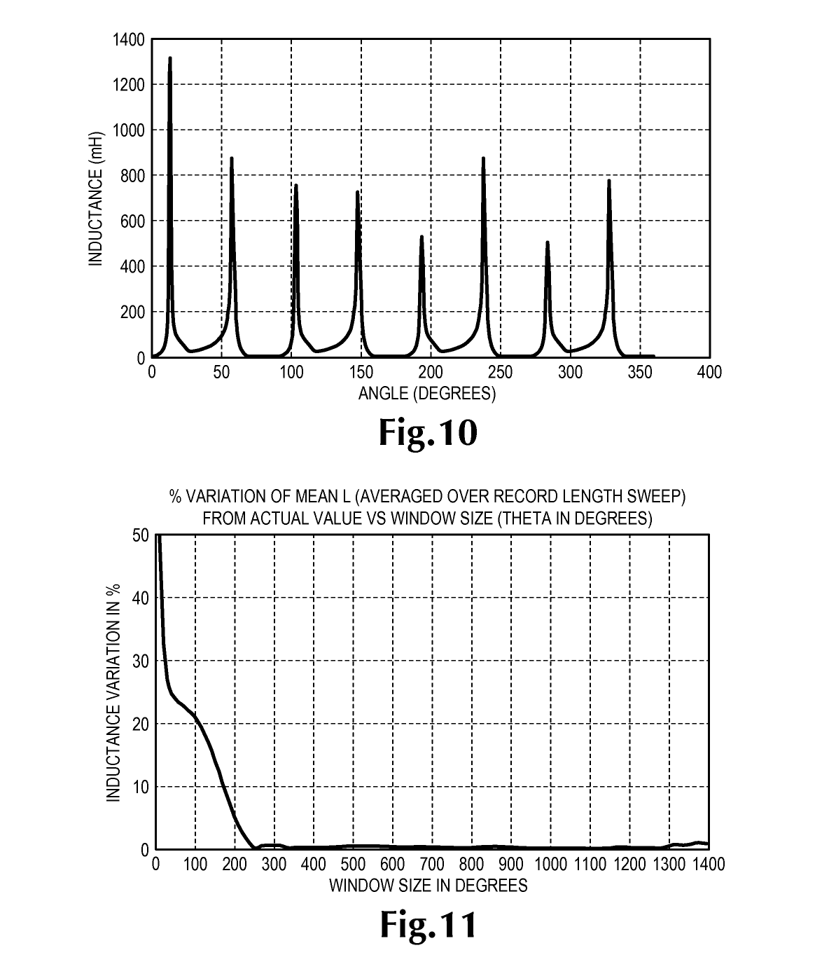

FIG. 10 shows a plot of variation of L versus scan window start point, when step size is further reduced to 2.8°. Then, the scan window is swept over the record length, and the results show variation of more than 200% in value of L.

FIG. 11 shows percentage variation of L versus varying step size or the window scan size. With fixed step size and varied starting point, it is found that when step size is less than 180°, variation of L is greater than 50%.

The method therefore allows a user to dynamically test the variation of inductances of motors such as AC motors. The change of inductances with different angular positioning of the rotor is made available enabling them to design better motors.

The foregoing description of the invention has been described for purposes of clarity and understanding. It is not intended to limit the invention to the precise form disclosed. Various modifications may be possible within the scope and equivalence of the appended claims.

We claim:

1. An apparatus for dynamic measurement of inductance trend of a motor comprising:
an input means for acquiring inputs signals from a motor;
a trigger system for defining acquisition cycle in accordance with the instructions from a programming unit;
a deflection subsystem for dynamic representation based on step size in accordance with the instruction from programming unit;
the programming unit configured to control the said trigger system and deflection subsystem and calculate induction with respect to rotor angle by repeated dynamic analysis of input signals from the motor for a chosen step size.

2. The apparatus for dynamic measurement of inductance trend of motor as in claim 1, wherein the apparatus is configured to obtain input of step size from user.

3. The apparatus for dynamic measurement of inductance trend of motor as in claim 1, wherein the programming unit is configured to measure inductance using the B-H curve method.

4. The apparatus for dynamic measurement of inductance trend of motor as in claim 1, wherein the programming unit is configured to repeat dynamically the method for calculating inductance for the whole record length for given step size.

5. The apparatus for dynamic measurement of inductance trend of motor as in claim 1, wherein the input means may comprise of input signal probes.

6. The apparatus for dynamic measurement of inductance trend of motor as in claim 1, wherein the apparatus is a digital oscilloscope.

7. A method for dynamic measurement of inductance trend of a motor comprising the steps of:
acquiring input signal from a motor;
receiving a step size for analysis from a user;
calculating the inductance by dynamic analysis of the input signal for a chosen step size.

8. The method for dynamic measurement of inductance trend of a motor as in claim 7, wherein the inductance is measured using the B-H curve method.

9. The method for dynamic measurement of inductance trend of a motor as in claim 7, including the step of performing time to degree conversion of the input signals.

10. The method for dynamic measurement of inductance trend of a motor as in claim 7, wherein the integral of the voltage waveform is obtained using trapezoidal method.

11. The method for dynamic measurement of inductance trend of a motor as in claim 7, comprising the step of repeating dynamic analysis of input signals from the motor for a chosen step size.
